(19) United States
(12) Patent Application Publication
(10) Pub. No.: US 2019/0297752 A1
(43) Pub. Date: Sep. 26, 2019

(54) INVERTER DEVICE AND VEHICLE

(71) Applicant: NIDEC TOSOK CORPORATION, Kanagawa (JP)

(72) Inventor: Yoshihisa OKUHATA, Kanagawa (JP)

(73) Assignee: NIDEC TOSOK CORPORATION, Kanagawa (JP)

(21) Appl. No.: 16/360,042

(22) Filed: Mar. 21, 2019

(30) Foreign Application Priority Data
Mar. 23, 2018 (JP) 2018-056278

(51) Int. Cl. H05K 7/20

(52) U.S. Cl. CPC H05K 7/20927

(57) ABSTRACT

There is provided an inverter device having features regarding the disposition of components. The inverter device includes an inverter unit and a housing in which the inverter unit is housed. The inverter unit includes a heating element, the housing has a partition wall having a cooling flow path through which a refrigerant flows and a plurality of fixing parts for fixing the heating element to the partition wall, the plurality of fixing parts include a first fixing part disposed at one side of the heating element and a second fixing part disposed at the other side of the heating element, and the cooling flow path is positioned between the first fixing part and the second fixing part.

### CROSS-REFERENCE TO RELATED APPLICATION

This application claims the priority of Japan patent application serial no. 2018-056278, filed on Mar. 23, 2018. The entirety of the above-mentioned patent application is hereby incorporated by reference herein and made a part of this specification.

### BACKGROUND

### Technical Field

The disclosure relates to an inverter device and vehicle.

### Description of Related Art

In recent years, the demand for high efficiency and high output in motors has been increasing. In order to realize high efficiency and high output in motors, it is necessary to cause a high current to flow and it is necessary to perform control to optimize timings. When a motor is driven with a high current in this manner, the influence of heat generated in the motor and components related to the driving thereof is not negligible. In particular, since components related to driving of a motor have an inverter device including a switching element with a large amount of heat being generated, it is important to perform cooling efficiently.

On the other hand, Patent Document 1 discloses a technology in which only necessary devices are intensively cooled according to an operation mode of an automobile with an electric motor, and the efficiency of a cooling pump is improved.

[Patent Document 1] Japanese Patent Laid-Open No. 2011-217557

In addition, in a motor and components related to driving thereof, respective components tend to increase in size along with the demand for high efficiency and high output in the motor. In this case, reducing the overall size of the device by restricting the disposition positions of components or the like becomes more important.

However, in Patent Document 1, although simple cooling of components is described, reducing the size of the device is not considered, and there is a problem that the disposition of components suitable for satisfying the demand for efficiently cooling and reducing the size of the device is not considered.

The disclosure provides an inverter device having features regarding the disposition of respective components.

### SUMMARY

An exemplary embodiment of the invention provides an inverter device including an inverter unit and a housing in which the inverter unit is housed, the inverter unit including a heating element, the housing having a partition wall having a cooling flow path through which a refrigerant flows, and a plurality of fixing parts for fixing the heating element to the partition wall, the plurality of fixing parts including a first fixing part disposed at one side of the heating element, and a second fixing part disposed at the other side of the heating element, and the cooling flow path being positioned between the first fixing part and the second fixing part.

An exemplary embodiment of the invention provides a vehicle, comprising: a motor; a battery; an inverter unit for motor driving configured to supply power from the battery to the motor; an inverter unit for a charger configured to charge the battery; and a housing in which the inverter unit for motor driving and the inverter unit for a charger are housed, wherein, in a vehicle that runs according to rotation of the motor, the inverter unit for motor driving has a heating element for motor driving, and the inverter unit for a charger includes a heating element for a charger, wherein the housing has a partition wall having a cooling flow path through which a refrigerant flows, a first fixing part for fixing one side of the heating element for motor driving to the partition wall, a second fixing part for fixing the other side of the heating element for motor driving to the partition wall, a third fixing part for fixing one side of the heating element for a charger to the partition wall, and a fourth fixing part for fixing the other side of the heating element for a charger to the partition wall, wherein the cooling flow path is positioned between the first fixing part and the second fixing part, and wherein the cooling flow path is positioned between the third fixing part and the fourth fixing part.

According to an exemplary embodiment of the invention, it is possible to provide an inverter device having features regarding the disposition of components.

### BRIEF DESCRIPTION OF THE DRAWINGS

FIG. 1 is a perspective view of an inverter device according to a first embodiment of the disclosure.

FIG. 2 is a block diagram showing a state in which an inverter device 1 in FIG. 1 is mounted in a vehicle.

FIG. 3 is a cross-sectional view of a housing 2 corresponding to the V-V arrow in FIG. 1 in the first embodiment of the disclosure.

FIG. 4 is a cross-sectional view of the housing 2 corresponding to the IV-IV arrow in FIG. 3.

FIG. 5 is a cross-sectional view of the housing 2 corresponding to the V-V arrow in FIG. 1 in the first embodiment of the disclosure.

FIG. 6 is a plan view of the housing 2 when viewed from above in the first embodiment of the disclosure.

FIG. 7 is a cross-sectional view of a housing 102 corresponding to the V-V arrow in FIG. 1 in a second embodiment of the disclosure.

FIG. 8 is a cross-sectional view of the housing 102 corresponding to the VIII-VIII arrow in FIG. 7.

FIG. 9 is a cross-sectional view of the housing 102 corresponding to the V-V arrow in FIG. 1 in the second embodiment of the disclosure.

FIG. 10 is a plan view of the housing 102 when viewed from above in the second embodiment of the disclosure.

FIG. 11 is a cross-sectional view of a housing 202 corresponding to the V-V arrow in FIG. 1 in a third embodiment of the disclosure.

FIG. 12 is a cross-sectional view of a housing 302 corresponding to the V-V arrow in FIG. 1 in a fourth embodiment of the disclosure.

FIG. 13 is a diagram for explaining a first modified example of the disclosure and is a cross-sectional view of the housing 102 corresponding to the XIII-XIII arrow in FIG. 9.

FIG. 14 is a perspective view of a second cooling flow path 120b in FIG. 13.

FIG. 15 is a diagram corresponding to FIG. 13 and is a cross-sectional view of a housing 402 of the first modified example.

FIG. 16 is a perspective view of a second cooling flow path 420b in FIG. 15. FIG. 17 is a perspective view of cooling flow paths 520b and 620b of a second modified example.

FIG. 18 is a perspective view of a cooling flow path 720b of a third modified example.

### DESCRIPTION OF THE EMBODIMENTS

Inverter devices according to embodiments of the disclosure will be described below with reference to the drawings. While an inverter device that drives a traction motor that causes a vehicle to run is described in the present embodiment, the disclosure is not limited thereto and can be applied to any inverter device. In addition, in the following drawings, in order to allow respective components to be easily understood, the sizes and numbers in the structures may be different those in actual structures.

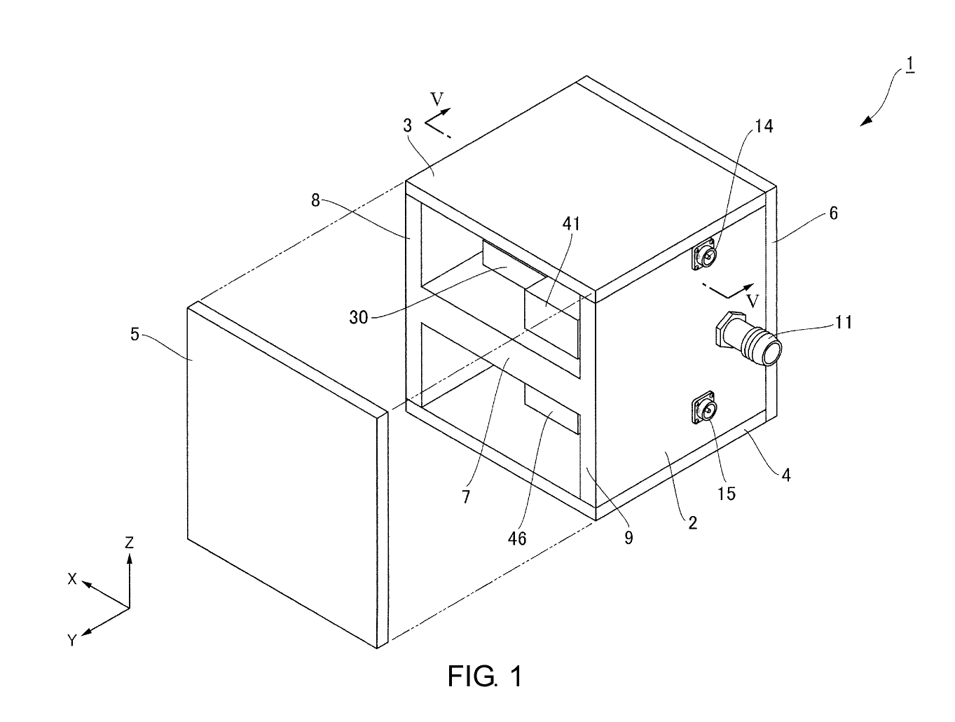

In addition, in the drawings, an XYZ coordinate system is appropriately shown as a three-dimensional orthogonal coordinate system. In the XYZ coordinate system, the Z axis direction is a direction orthogonal to a surface of a partition wall 7 shown in FIG. 1, the Y axis direction is a direction orthogonal to a surface of a front lid 5 shown in FIG. 1, and the X axis direction is a direction parallel to both the surface of the partition wall 7 and the surface of the front lid 5 shown in FIG. 1, that is, the X axis direction is a direction orthogonal to both the Z axis direction and the Y axis direction.

Here, in this specification, the term “extending in the Z axis direction” includes not only extending strictly in the Z axis direction but also extending in a direction inclined in a range of less than 45° with respect to the Z axis direction.

In addition, in this specification, directions such as forward, rearward, left, right, upward and downward indicate directions viewed in the drawings and do not limit directions when a device according to the disclosure is used.

### First Embodiment

### <Overall Configuration>

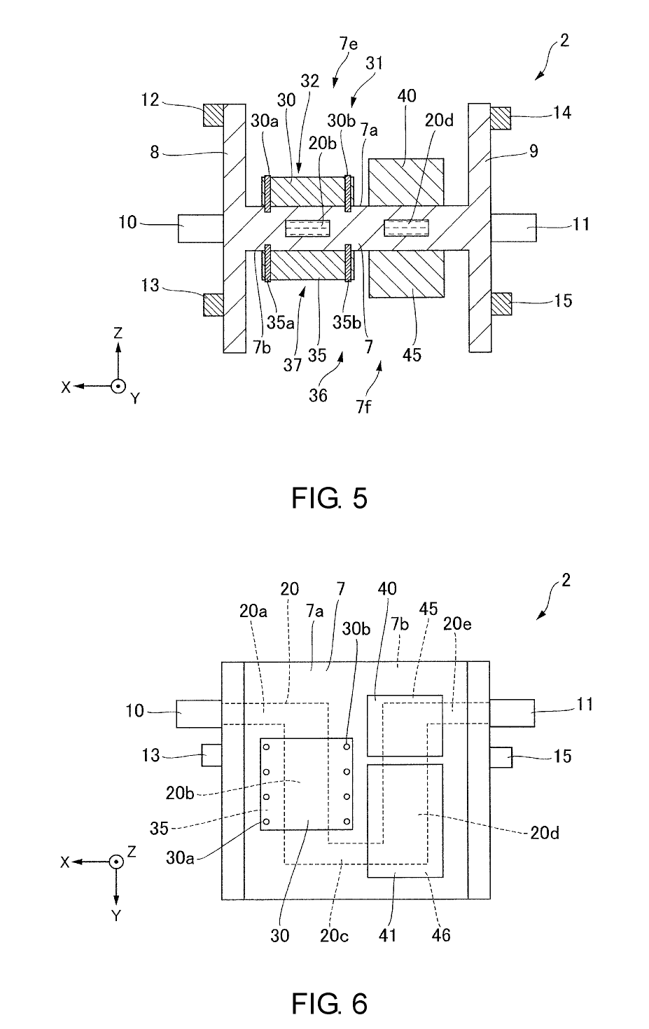

FIG. 1 is a perspective view of an inverter device according to a first embodiment. An inverter device 1 of the present embodiment includes a housing 2 including a partition wall 7, a first side wall 8, and a second side wall 9, an upper lid 3 for blocking an opening on the upper side (+Z direction) of the housing 2, a lower lid 4 for blocking an opening on the lower side (−Z direction) of the housing 2, a front lid 5 for blocking an opening on the front side (+Y direction) of the housing 2, a rear lid 6 for blocking an opening on the rear side (−Y direction) of the housing 2, a motor drive device 31 (refer to FIG. 5), and a charger 36 (refer to FIG. 5).

The housing 2 is, for example, die cast. The partition wall 7, the first side wall 8, and the second side wall 9 are an integrally molded single member. The housing 2, the upper lid 3, the lower lid 4, the front lid 5, and the rear lid 6 are fixed with, for example, bolts.

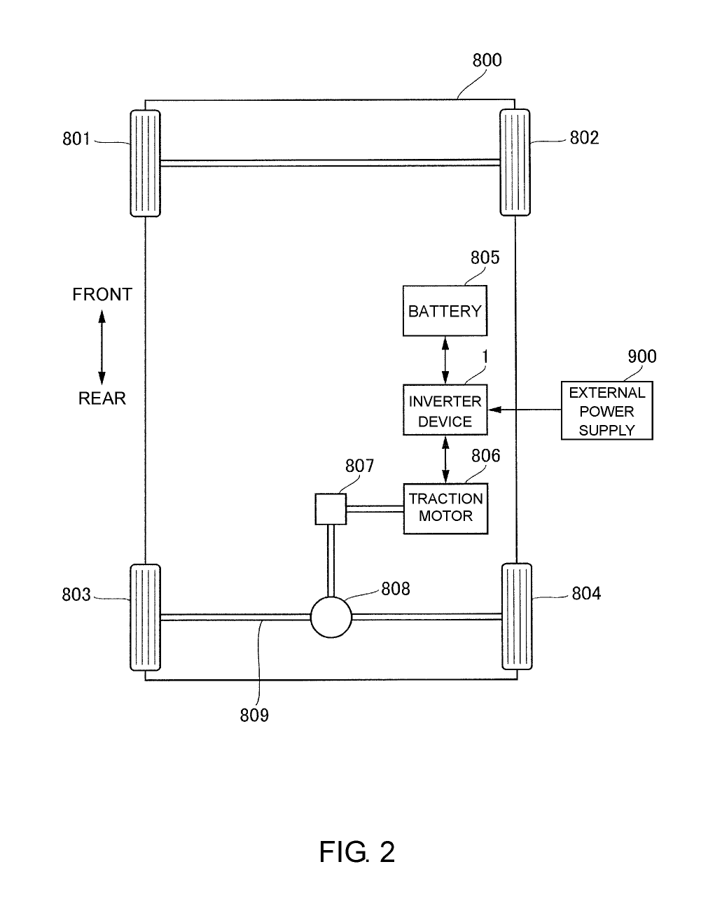

FIG. 2 is a block diagram showing a state in which the inverter device in FIG. 1 is mounted in a vehicle. A vehicle 800 includes a left front wheel 801, a right front wheel 802, a left rear wheel 803, a right rear wheel 804, the inverter device 1 shown in FIG. 1, a battery 805, a traction motor 806, a transmission 807, a differential gear 808, and an axle shaft 809. The vehicle 800 runs using four wheels including the left front wheel 801, the right front wheel 802, the left rear wheel 803, and the right rear wheel 804.

A DC voltage from the battery 805 is converted into a three-phase AC voltage by the inverter device 1 and is supplied to the traction motor 806, and thereby the traction motor 806 rotates. Rotation of the traction motor 806 is transmitted to the left rear wheel 803 and the right rear wheel 804 via the transmission 807, the differential gear 808, and the axle shaft 809. While FIG. 2 shows an example of driving with rear wheels, the vehicle 800 may be driven with front wheels or driven with four wheels. The inverter device 1 has the motor drive device 31 configured to supply power from the battery 805 to the traction motor 806.

An external power supply 900 is, for example, a charging stand. For example, when the vehicle 800 is stopped, the inverter device 1 is connected to the external power supply 900 and thus the battery 805 is charged with a voltage from the external power supply 900 via the inverter device 1. The inverter device 1 has the charger 36 configured to charge the battery 805.

Respective components shown in FIG. 2 operate under control of an electronic control unit (ECU, not shown) mounted on the vehicle 800.

<Housing 2>

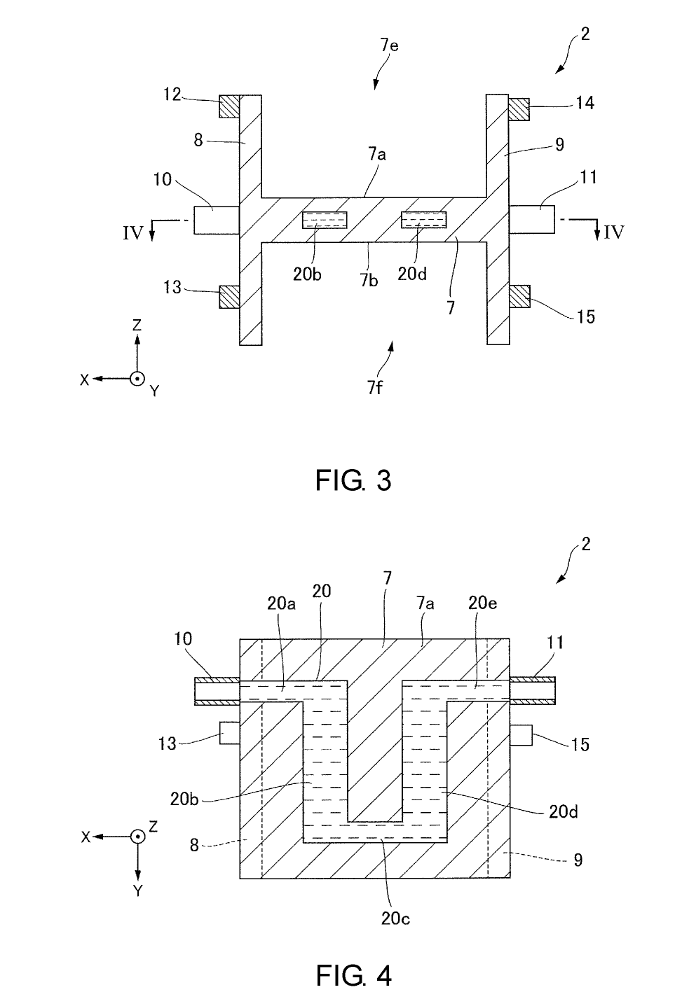

FIG. 3 is a cross-sectional view of the housing 2 corresponding to the V-V arrow in FIG. 1. FIG. 4 is a cross-sectional view of the housing 2 corresponding to the IV-IV arrow in FIG. 3. In FIG. 3 and FIG. 4, the motor drive device 31 and the charger 36 are not shown. As shown in FIG. 5, the housing 2 houses the motor drive device 31 and the charger 36. The partition wall 7 of the housing 2 is a rectangular flat plate member and has surfaces parallel to the Y axis direction and extending in a direction parallel to the X axis direction. Among surfaces of the partition wall 7, a surface on the upper side (+Z direction side) in FIG. 3 is referred to as a first surface 7a, and a surface on the lower side (−Z direction side) in FIG. 3 is referred to as a second surface 7b. The second surface 7b is a reverse surface with respect to the first surface 7a.

The first side wall 8 extends to both sides including a side (+Z direction side) protruding from the first surface 7a and a side (−Z direction side) protruding from the second surface 7b at one end in the X axis direction (+X direction side end) of the partition wall 7. The second side wall 9 extends to both sides including a side (+Z direction side) protruding from the first surface 7a and a side (−Z direction side) protruding from the second surface 7b at the other end in the X axis direction (−X direction side end) of the partition wall 7. The first side wall 8, the second side wall 9, and the partition wall 7 form an H shape.

Among surfaces of the first side wall 8, on the surface that extends to the side (+Z direction side) protruding from the first surface 7a and on the surface outside (+X direction side) the inverter device 1, a battery connecting part 12 that protrudes outward (+X direction side) from the inverter device 1 is provided. The battery 805 and the motor drive device 31 are connected via the battery connecting part 12. The battery connecting part 12 and the battery 805 are connected through a cable (not shown).

Among surfaces of the first side wall 8, on the surface that extends to the side (−Z direction side) protruding from the second surface 7b and on the surface outside (+X direction side) the inverter device 1, an external power supply connecting part 13 that protrudes outward (+X direction side) from the inverter device 1 is provided. The external power supply 900 and the charger 36 are connected via the external power supply connecting part 13. The external power supply connecting part 13 and the external power supply 900 are connected through a cable (not shown).

Among surfaces of the second side wall 9, on the surface that extends to the side (+Z direction side) protruding from the first surface 7a and on the surface outside (−X direction side) the inverter device 1, a motor connecting part 14 that protrudes outward (−X direction side) from the inverter device 1 is provided. The motor drive device 31 and the traction motor 806 are connected via the motor connecting part 14. The housing 2 has the motor connecting part 14 connected to the traction motor 806. The motor connecting part 14 and the traction motor 806 are connected through a cable (not shown).

Among surfaces of the second side wall 9, on the surface that extends to the side (−Z direction side) protruding from the second surface 7b and on the surface outside (−X direction side) the inverter device 1, a battery connecting part 15 that protrudes outward (−X direction side) from the inverter device 1 is provided. The charger 36 and the battery 805 are connected via the battery connecting part 15. The battery connecting part 15 and the battery 805 are connected through a cable (not shown).

<First Housing Part 7e and Second Housing Part 7f>

The housing 2 has a first housing part 7e in which the motor drive device 31 is housed and a second housing part 7f in which the charger 36 is housed. The partition wall 7 partitions the first housing part 7e from the second housing part 7f. The first housing part 7e is partitioned off by the side of the first surface 7a of the partition wall 7, the first side wall 8, and the second side wall 9. The second housing part 7f is partitioned off by the side of the second surface 7b of the partition wall 7, the first side wall 8, and the second side wall 9.

The first housing part 7e has the battery connecting part 12 connected to the battery 805.

The first housing part 7e has the motor connecting part 14 connected to the traction motor 806. The second housing part 7f has the external power supply connecting part 13 connected to the external power supply 900. The second housing part 7f has the battery connecting part 15 connected to the battery 805.

<Cooling Flow Path 20>

The partition wall 7 has a cooling flow path 20 through which a refrigerant that cools components provided in the inverter device 1 flows. As the refrigerant, a liquid such as an antifreezing liquid or a gas can be used. In the present embodiment, a liquid is used as the refrigerant. The refrigerant flowing through the cooling flow path 20 is supplied to the inverter device 1 via an inlet 10 by a pump (not shown). The refrigerant flowing through the cooling flow path 20 is discharged from the inverter device 1 via an outlet 11 and returns to the pump.

The inlet 10 protrudes to the +X direction side at one end in the X axis direction (+X direction side end) of the partition wall 7. In other words, the inlet 10 protrudes to the +X direction side at a position on the partition wall 7 in the Z axis direction within the first side wall 8. That is, the inlet 10 is disposed on the first side wall 8. The outlet 11 protrudes to the −X direction side at the other end in the X axis direction (−X direction side end) of the partition wall 7. In other words, the outlet 11 protrudes to the −X direction side at a position on the partition wall 7 in the Z axis direction within the second side wall 9. That is, the outlet 11 is disposed on the second side wall 9. Both the inlet 10 and the outlet 11 may be disposed on the first side wall 8. In this case, it is possible to secure the length of the cooling flow path 20 returning to the first side wall 8 via the partition wall 7 from the first side wall 8.

The cooling flow path 20 has a first cooling flow path 20a, a second cooling flow path 20b, a third cooling flow path 20c, a fourth cooling flow path 20d, and a fifth cooling flow path 20e. The first cooling flow path 20a is connected to the inlet 10 at the +X direction side end and extends to the −X direction side. The second cooling flow path 20b is connected to the −X direction side end of the first cooling flow path 20a at the −Y direction side end and extends to the +Y direction side. The third cooling flow path 20c is connected to the +Y direction side end of the second cooling flow path 20b at the +X direction side end and extends to the −X direction side. The fourth cooling flow path 20d is connected to the −X direction side end of the third cooling flow path 20c at the +Y direction side end and extends to the −Y direction side. The fifth cooling flow path 20e is connected to the −Y direction side end of the fourth cooling flow path 20d at the +X direction side end, extends to the −X direction side and is connected to the outlet 11 at the −X direction side end.

As shown in FIG. 3, on the surface orthogonal to a direction in which a refrigerant flows through the cooling flow path 20 (a direction from the inlet 10 toward the outlet 11), a cross-sectional shape of the cooling flow path 20 is a rectangle. FIG. 3 shows a cross-sectional shape of the second cooling flow path 20b and the fourth cooling flow path 20d. The refrigerant flowing through the cooling flow path 20 can cool a component disposed on the first surface 7a of the partition wall 7 and a component disposed on the second surface 7b of the partition wall 7.

<Motor Drive Device 31>

FIG. 5 is a cross-sectional view of the housing 2 corresponding to the V-V arrow in FIG. 1. FIG. 6 is a plan view of the housing 2 when viewed from above. The motor drive device 31 includes an inverter unit for motor driving 32, a reactor 40, and a condenser 41. The inverter unit for motor driving 32 is a first inverter unit. The inverter unit for motor driving 32 includes a circuit board (not shown) and a first heating element 30 that generates heat. The first heating element 30 is formed of, for example, a plurality of switching elements housed in a casing. The plurality of switching elements of the first heating element 30 are, for example, insulated gate bipolar transistors (IGBTs). The first heating element 30 may include another switching element such as an FET. The first heating element 30 may be a single switching element. The first heating element 30 may be a heating element other than a switching element. The inverter unit for motor driving 32 performs DC/AC conversion according to switching control of the first heating element 30.

<Charger 36>

The charger 36 includes an inverter unit for a charger 37, a reactor 45, and a condenser 46. The inverter unit for a charger 37 is a second inverter unit. The inverter unit for a charger 37 includes a circuit board (not shown) and a second heating element 35 that generates heat. The second heating element 35 is formed of, for example, a plurality of switching elements housed in a casing. The plurality of switching elements of the second heating element 35 are, for example, IGBTs. The second heating element 35 may be another switching element such as an FET. The second heating element 35 may be a single switching element. The second heating element 35 may be a heating element other than a switching element. The inverter unit for a charger 37 performs DC/AC conversion according to switching control of the second heating element 35.

<Disposition of First Heating Element 30 and Second Heating Element 35>

The first heating element 30, the reactor 40 and the condenser 41 are housed in the first housing part 7e. The first heating element 30, the reactor 40, and the condenser 41 are disposed in contact with the first surface 7a of the partition wall 7. The second heating element 35, the reactor 45 and the condenser 46 are housed in the second housing part 7f. The second heating element 35, the reactor 45 and the condenser 46 are disposed in contact with the second surface 7b of the partition wall 7.

The first heating element 30 is disposed to face the second cooling flow path 20b. The reactor 40 is disposed to face the fourth cooling flow path 20d and the fifth cooling flow path 20e. The condenser 41 is disposed to face the third cooling flow path 20c and the fourth cooling flow path 20d. The second heating element 35 is disposed to face the second cooling flow path 20b. The reactor 45 is disposed to face the fourth cooling flow path 20d and the fifth cooling flow path 20e. The condenser 46 is disposed to face the third cooling flow path 20c and the fourth cooling flow path 20d. The first heating element 30 is disposed at a position facing the second heating element 35 with the cooling flow path 20 therebetween.

According to the present embodiment, the first heating element 30 is fixed to the first surface 7a of the partition wall 7 having the cooling flow path 20, and the second heating element 35 is fixed to the second surface 7b. Therefore, it is possible to efficiently cool the first heating element 30 and the second heating element 35 with the refrigerant flowing through the cooling flow path 20, and it is possible to reduce the size of the device by effectively utilizing a space in which the first heating element 30, the second heating element 35, and the cooling flow path 20 are disposed.

The first heating element 30 is fixed to the first surface 7a of the partition wall 7 with a first fixing part 30a and a second fixing part 30b. The first fixing part 30a and the second fixing part 30b are, for example, a bolt. As shown in FIG. 5, the second cooling flow path 20b facing the first heating element 30 in the Z axis direction is positioned between the first fixing part 30a and the second fixing part 30b. The second heating element 35 is fixed to the second surface 7b of the partition wall 7 with a first fixing part 35a and a second fixing part 35b. The first fixing part 35a and the second fixing part 35b are, for example, a bolt. As shown in FIG. 5, the second cooling flow path 20b facing the second heating element 35 in the Z axis direction is positioned between the first fixing part 35a and the second fixing part 35b.

In FIG. 5, the thickness of the partition wall 7 between the second cooling flow path 20b and the first heating element 30 at a position at which the second cooling flow path 20b faces the first heating element 30 is larger than the length of the first fixing part 30a, and the thickness of the partition wall 7 between the second cooling flow path 20b and the first heating element 30 at a position at which the second cooling flow path 20b faces the first heating element 30 is larger than the length of the second fixing part 30b. The length of the first fixing part 30a may be larger than the thickness of the partition wall 7 between the second cooling flow path 20b and the first heating element 30 at the position at which the second cooling flow path 20b faces the first heating element 30, and the length of the second fixing part 30b may be larger than the thickness of the partition wall 7 between the second cooling flow path 20b and the first heating element 30 at the position at which the second cooling flow path 20b faces the first heating element 30.

The cooling flow path 20 is positioned between the first fixing part 30a and the second fixing part 30b. Therefore, the cooling flow path 20 can be disposed at a position at which the first heating element 30 can be cooled, and it is possible to efficiently cool the first heating element 30 with the refrigerant flowing through the cooling flow path 20. The cooling flow path 20 is positioned between the first fixing part 35a and the second fixing part 35b. Therefore, the cooling flow path 20 can be disposed at a position at which the second heating element 35 can be cooled, and it is possible to efficiently cool the second heating element 35 with the refrigerant flowing through the cooling flow path 20.

Here, in a direction orthogonal to the direction in which the refrigerant flows through the second cooling flow path 20b, the width of a region occupied by the first heating element 30 facing the first surface 7a of the partition wall 7 is longer than the width of the cross section of the second cooling flow path 20b. In the direction orthogonal to the direction in which the refrigerant flows through the second cooling flow path 20b, the width of a region occupied by the second heating element 35 facing the second surface 7b of the partition wall 7 is longer than the width of the cross section of the second cooling flow path 20b. Therefore, the width of the cross section of the second cooling flow path 20b does not deviate from a part to be cooled, and thus it is possible to efficiently cool the first heating element 30 and the second heating element 35 along the second cooling flow path 20b, and it is possible to reduce the size of the inverter device 1 by effectively utilizing a space in which the first heating element 30, the second heating element 35, and the second cooling flow path 20b are disposed.

In FIG. 5, the cross-sectional shape of the second cooling flow path 20b is a rectangle, but the disclosure is not limited thereto, and the cross-sectional shape may be another shape. For example, a case in which the width (the length in the X axis direction) of the cross section of the second cooling flow path 20b is longer than the length between the first fixing part 30a and the second fixing part 30b may be considered. In this case, the thickness of the partition wall 7 between the second cooling flow path 20b and the first heating element 30 at the position at which the second cooling flow path 20b faces the first heating element 30 may be thinner than the thickness of the partition wall 7 at the position of the first fixing part 30a. Thereby, it is possible to cool the first heating element 30 more efficiently by bringing the refrigerant flowing through the second cooling flow path 20b closer thereto.

### Second Embodiment

### <Housing 102>

An appearance of an inverter device according to a second embodiment is the same as that of the inverter device according to the first embodiment shown in FIG. 1. In addition, a state in which the inverter device according to the second embodiment is mounted in a vehicle is the same as in FIG. 2. Here, the second embodiment of the disclosure will be described with reference to FIG. 1 and FIG. 2. In the second embodiment, components the same as in the first embodiment will be denoted with the same reference numerals. In the second embodiment, the inverter device 1 has a housing 102 in place of the housing 2 of the first embodiment. In the second embodiment, unless otherwise noted, components in place of the components in the first embodiment are the same components in the first embodiment.

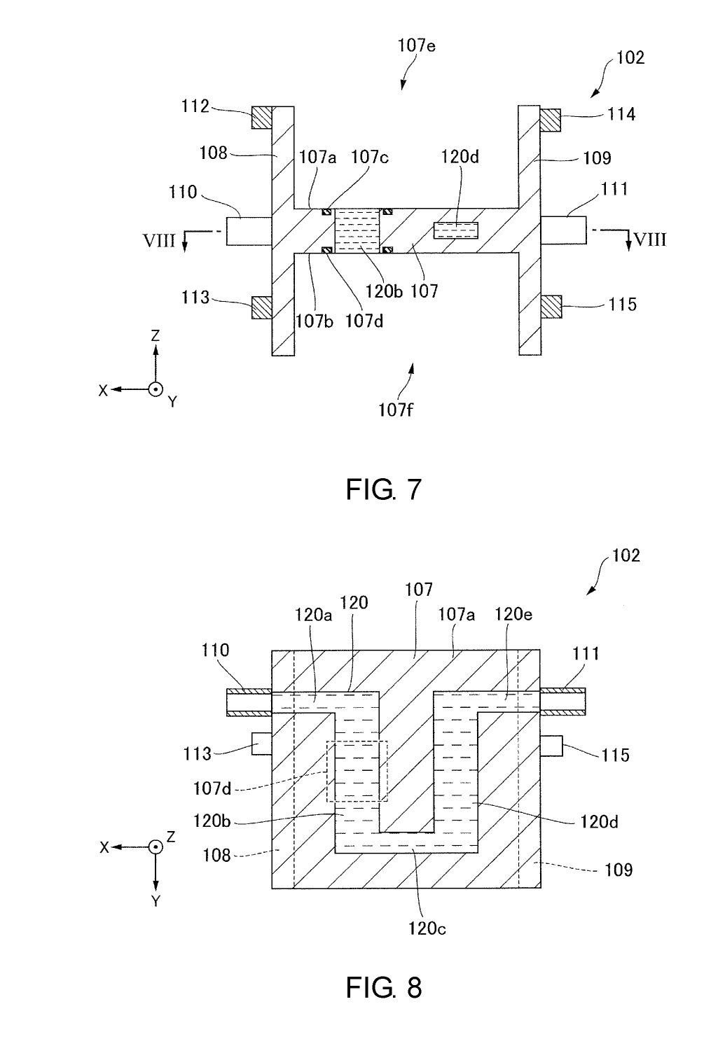

FIG. 7 is a cross-sectional view of the housing 102 corresponding to the V-V arrow in FIG. 1. FIG. 8 is a cross-sectional view of the housing 102 corresponding to the VIII-VIII arrow in FIG. 7. The housing 102 houses the motor drive device 31 and the charger 36. In FIG. 7 and FIG. 8, the motor drive device 31 and the charger 36 are not shown.

The housing 102 has a partition wall 107 in place of the partition wall 7 of the first embodiment. The housing 102 has a first housing part 107e in place of the first housing part 7e of the first embodiment. The housing 102 has a second housing part 107f in place of the second housing part 7f of the first embodiment. The housing 102 has a first side wall 108 in place of the first side wall 8 of the first embodiment. The housing 102 has a second side wall 109 in place of the second side wall 9 of the first embodiment. The housing 102 has an inlet 110 in place of the inlet 10 of the first embodiment. The housing 102 has an outlet 111 in place of the outlet 11 of the first embodiment. The housing 102 has a battery connecting part 112 in place of the battery connecting part 12 of the first embodiment. The housing 102 has an external power supply connecting part 113 in place of the external power supply connecting part 13 of the first embodiment. The housing 102 has a motor connecting part 114 in place of the motor connecting part 14 of the first embodiment. The housing 102 has a battery connecting part 115 in place of the battery connecting part 15 of the first embodiment.

The housing 102 has a cooling flow path 120 in place of the cooling flow path 20 of the first embodiment. The partition wall 107 has a first surface 107a in place of the first surface 7a of the first embodiment. The partition wall 107 has a second surface 107b in place of the second surface 7b of the first embodiment. The partition wall 107 has a seal part 107c. The partition wall 107 has a seal part 107d. The cooling flow path 120 has a first cooling flow path 120a in place of the first cooling flow path 20a of the first embodiment. The cooling flow path 120 has a second cooling flow path 120b in place of the second cooling flow path 20b of the first embodiment. The cooling flow path 120 has a third cooling flow path 120c in place of the third cooling flow path 20c of the first embodiment. The cooling flow path 120 has a fourth cooling flow path 120d in place of the fourth cooling flow path 20d of the first embodiment. The cooling flow path 120 has a fifth cooling flow path 120e in place of the fifth cooling flow path 20e of the first embodiment.

<Cooling Flow Path 120>

The second cooling flow path 120b of the cooling flow path 120 opens to the side (+Z direction side) of the first surface 107a and opens to the side (−Z direction side) of the second surface 107b. That is, the second cooling flow path 120b has a through-hole that penetrates through the side of the first surface 107a and a through-hole that penetrates through the side of the second surface 107b. The opening on the side of the first surface 107a of the second cooling flow path 120b is surrounded by the seal part 107c on the first surface 107a. In a region that is not surrounded by the seal part 107c, the second cooling flow path 120b does not open to the side (+Z direction side) of the first surface 107a. The opening on the side of the second surface 107b of the second cooling flow path 120b is surrounded by the seal part 107d on the second surface 107b. In a region that is not surrounded by the seal part 107d, the second cooling flow path 120b does not open to the side (−Z direction side) of the second surface 107b. The seal part 107c is, for example, an O-ring. When the seal part 107c is an O-ring, a groove is formed on the first surface 107a and the seal part 107c is fitted into the groove. The seal part 107d is, for example, an O-ring. When the seal part 107d is an O-ring, a groove is formed on the second surface 107b and the seal part 107d is fitted into the groove.

In the present embodiment, the shape of the seal part 107c and the seal part 107d is a rectangular ring shape as shown in FIG. 8, but it may be an annular shape. In the present embodiment, the shape of the opening on the side of the first surface 107a of the second cooling flow path 120b is a rectangle on the surface parallel to the first surface 107a, but it may be a circle or another shape. In the present embodiment, the shape of the opening on the side of the second surface 107b of the second cooling flow path 120b is a rectangle on the surface parallel to the second surface 107b, but it may be a circle or another shape. In the present embodiment, the shape of the opening on the side of the first surface 107a of the second cooling flow path 120b is the same as the shape of the opening on the side of the second surface 107b of the second cooling flow path 120b. However, as another embodiment, the shape of the opening on the side of the first surface 107a of the second cooling flow path 120b may be different from the shape of the opening on the side of the second surface 107b of the second cooling flow path 120b.

<Disposition of First Heating Element 30 and Second Heating Element 35>

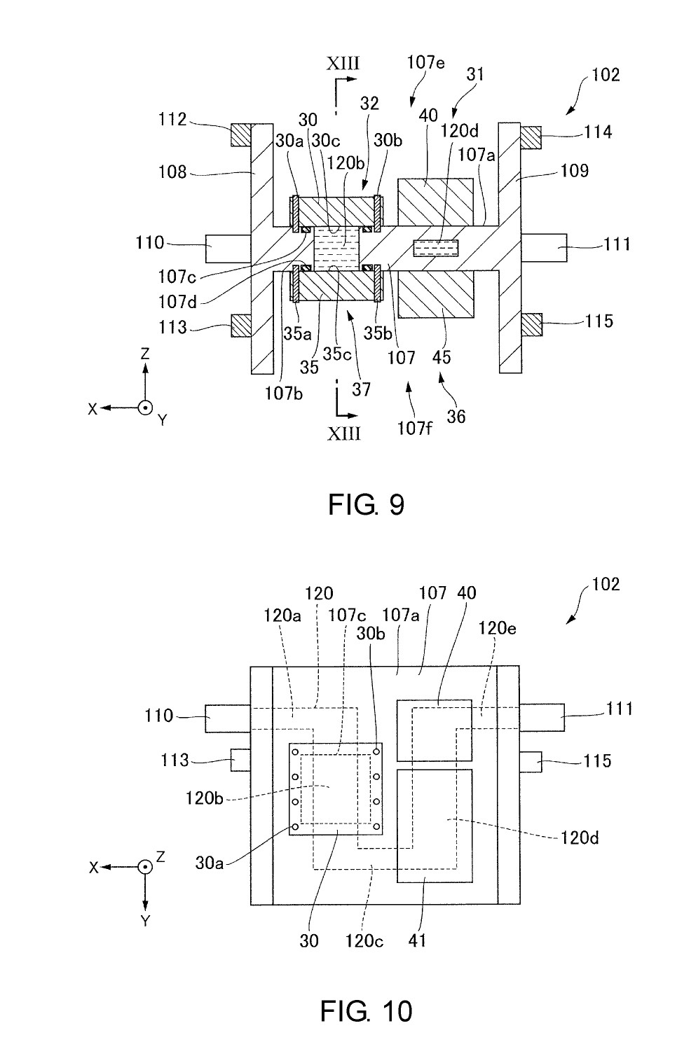

FIG. 9 is a cross-sectional view of the housing 102 corresponding to the V-V arrow in FIG. 1. FIG. 10 is a plan view of the housing 102 shown in FIG. 9 when viewed from above. The first heating element 30, the reactor 40 and the condenser 41 are housed in the first housing part 107e. The first heating element 30 has a cooling surface 30c which is an end surface subjected to waterproofing. In the first heating element 30, the cooling surface 30c is in contact with the first surface 107a of the partition wall 107 and is disposed on the first surface 107a. The reactor 40 and the condenser 41 are disposed in contact with the first surface 107a of the partition wall 107. The second heating element 35, the reactor 45, and the condenser 46 are housed in the second housing part 107f. The second heating element 35 has a cooling surface 35c which is an end surface subjected to waterproofing. In the second heating element 35, the cooling surface 35c is in contact with the second surface 107b of the partition wall 107 and is disposed on the second surface 107b. The reactor 45 and the condenser 46 are disposed in contact with the second surface 107b of the partition wall 107.

The first heating element 30 is disposed to face the second cooling flow path 120b. The reactor 40 is disposed to face the fourth cooling flow path 120d and the fifth cooling flow path 120e. The condenser 41 is disposed to face the third cooling flow path 120c and the fourth cooling flow path 120d. The second heating element 35 is disposed to face the second cooling flow path 120b. The reactor 45 is disposed to face the fourth cooling flow path 120d and the fifth cooling flow path 120e. The condenser 46 is disposed to face the third cooling flow path 120c and the fourth cooling flow path 120d.

The first heating element 30 is disposed at a position at which the opening on the side of the first surface 107a of the second cooling flow path 120b is blocked. That is, the first heating element 30 covers a through-hole that penetrates through the side of the first surface 107a. The seal part 107c seals between the first surface 107a of the partition wall 107 and the cooling surface 30c of the first heating element 30. When a refrigerant flows through the cooling flow path 120, on the opening on the side of the first surface 107a of the second cooling flow path 120b, the refrigerant is in contact with the cooling surface 30c of the first heating element 30. That is, the cooling surface 30c which is an end surface of the first heating element 30 forms a flow path wall of the cooling flow path 120. Therefore, it is possible to cool the first heating element 30 of the inverter unit for motor driving 32 more efficiently.

The second heating element 35 is disposed at a position at which the opening on the side of the second surface 107b of the second cooling flow path 120b is blocked. That is, the second heating element 35 covers a through-hole that penetrates through the side of the second surface 107b. The seal part 107d seals between the second surface 107b of the partition wall 107 and the cooling surface 35c of the second heating element 35. When a refrigerant flows through the cooling flow path 120, on the opening on the side of the second surface 107b of the second cooling flow path 120b, the refrigerant is in contact with the cooling surface 35c of the second heating element 35. That is, the cooling surface 35c which is an end surface of the second heating element 35 forms a flow path wall of the cooling flow path 120. Therefore, it is possible to cool the second heating element 35 of the inverter unit for a charger 37 more efficiently.

[Third embodiment] An appearance of an inverter device according to a third embodiment is the same as that of the inverter device according to the first embodiment shown in FIG. 1. In addition, a state in which the inverter device according to the third embodiment is mounted in a vehicle is the same as in FIG. 2. Here, the third embodiment of the disclosure will be described with reference to FIG. 1 and FIG. 2. In the third embodiment, components the same as in the first embodiment and the second embodiment will be denoted with the same reference numerals. In the third embodiment, the inverter device 1 has a housing 202 in place of the housing 2 of the first embodiment. In the third embodiment, unless otherwise noted, components in place of the components in the first embodiment and the second embodiment are the same components in the first embodiment and the second embodiment.

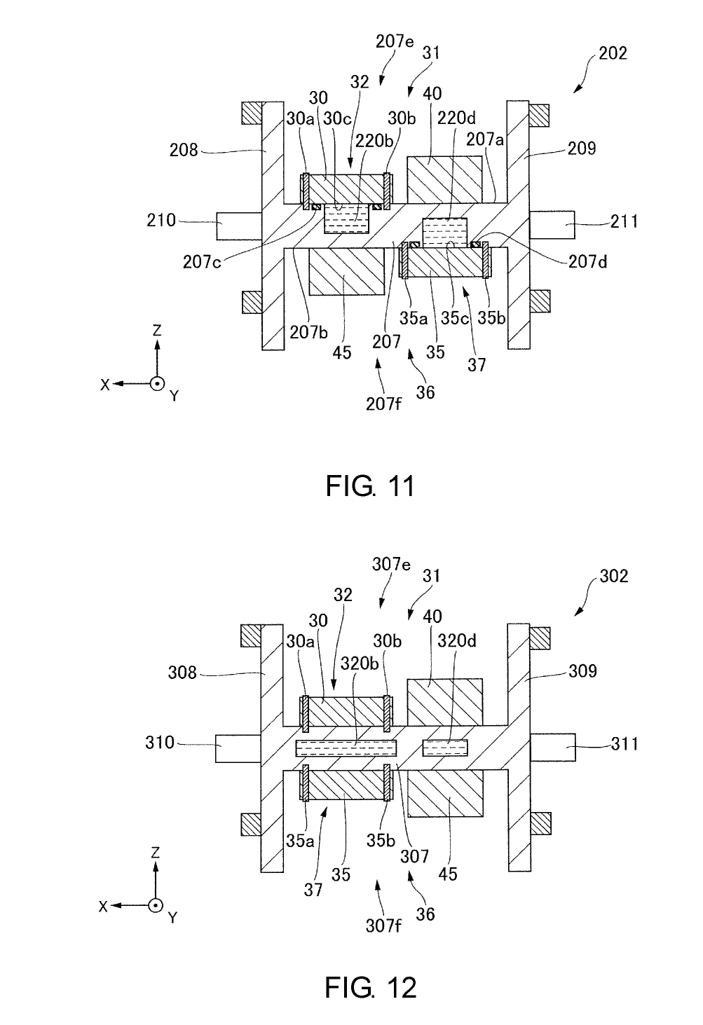

FIG. 11 is a cross-sectional view of the housing 202 corresponding to the V-V arrow in FIG. 1. The housing 202 houses the motor drive device 31 and the charger 36.

The housing 202 has a partition wall 207 in place of the partition wall 7 of the first embodiment. The housing 202 has a first housing part 207e in place of the first housing part 7e of the first embodiment. The housing 202 has a second housing part 207f in place of the second housing part 7f of the first embodiment. The housing 202 has a first side wall 208 in place of the first side wall 8 of the first embodiment. The housing 202 has a second side wall 209 in place of the second side wall 9 of the first embodiment. The housing 202 has an inlet 210 in place of the inlet 10 of the first embodiment. The housing 202 has an outlet 211 in place of the outlet 11 of the first embodiment. The housing 202 has a battery connecting part 212 in place of the battery connecting part 12 of the first embodiment. The housing 202 has an external power supply connecting part 213 in place of the external power supply connecting part 13 of the first embodiment. The housing 202 has a motor connecting part 214 in place of the motor connecting part 14 of the first embodiment. The housing 202 has a battery connecting part 215 in place of the battery connecting part 15 of the first embodiment.

The partition wall 207 has a first surface 207a in place of the first surface 7a of the first embodiment. The partition wall 207 has a second surface 207b in place of the second surface 7b of the first embodiment. The partition wall 207 has a seal part 207c in place of the seal part 107c of the second embodiment. The partition wall 207 has a seal part 207d in place of the seal part 107d of the second embodiment. The partition wall 207 has a second cooling flow path 220b in place of the second cooling flow path 20b of the first embodiment. The partition wall 207 has a fourth cooling flow path 220d in place of the fourth cooling flow path 20d of the first embodiment.

<Second Cooling Flow Path 220b>

A second cooling flow path 220b opens to the side (+Z direction side) of the first surface 207a. The second cooling flow path 220b does not open to the side (−Z direction side) of the second surface 207b. The opening on the side of the first surface 207a of the second cooling flow path 220b is surrounded by the seal part 207c on the first surface 207a. In a region that is not surrounded by the seal part 207c, the second cooling flow path 220b does not open to the side (+Z direction side) of the first surface 207a.

<Fourth Cooling Flow Path 220d>

The fourth cooling flow path 220d opens to the side (−Z direction side) of the second surface 207b. The fourth cooling flow path 220d does not open to the side (+Z direction side) of the first surface 207a. The opening on the side of the second surface 207b of the fourth cooling flow path 220d is surrounded by the seal part 207d on the second surface 207b. In a region that is not surrounded by the seal part 207d, the fourth cooling flow path 220d does not open to the side (−Z direction side) of the second surface 207b.

<Disposition of First Heating Element 30 and Second Heating Element 35>

The first heating element 30 and the reactor 40 are housed in the first housing part 207e. In the first heating element 30, the cooling surface 30c is in contact with the first surface 207a of the partition wall 207 and is disposed on the first surface 207a. The reactor 40 is disposed in contact with the first surface 207a of the partition wall 207. The second heating element 35 and the reactor 45 are housed in the second housing part 207f. In the second heating element 35, the cooling surface 35c is in contact with the second surface 207b of the partition wall 207 and is disposed in the second surface 207b. The reactor 45 is disposed in contact with the second surface 207b of the partition wall 207.

The first heating element 30 is disposed to face the second cooling flow path 220b. The reactor 40 is disposed to face the fourth cooling flow path 220d. The second heating element 35 is disposed to face the fourth cooling flow path 220d. The reactor 45 is disposed to face the second cooling flow path 220b.

The first heating element 30 is disposed at a position at which the opening on the side of the first surface 207a of the second cooling flow path 220b is blocked. The seal part 207c seals between the first surface 207a of the partition wall 207 and the cooling surface 30c of the first heating element 30. When a refrigerant flows through the second cooling flow path 220b, on the opening on the side of the first surface 207a of the second cooling flow path 220b, the refrigerant is in contact with the cooling surface 30c of the first heating element 30. That is, the cooling surface 30c which is an end surface of the first heating element 30 forms a flow path wall of the second cooling flow path 220b. Therefore, it is possible to cool the first heating element 30 of the inverter unit for motor driving 32 more efficiently.

The second heating element 35 is disposed at a position at which the opening on the side of the second surface 207b of the fourth cooling flow path 220d is blocked. The seal part 207d seals between the second surface 207b of the partition wall 207 and the cooling surface 35c of the second heating element 35. When a refrigerant flows through the fourth cooling flow path 220d, on the opening on the side of the second surface 207b of the fourth cooling flow path 220b, the refrigerant is in contact with the cooling surface 35c of the second heating element 35. That is, the cooling surface 35c which is an end surface of the second heating element 35 forms a flow path wall of the fourth cooling flow path 220d. Therefore, it is possible to cool the second heating element 35 of the inverter unit for a charger 37 more efficiently.

[Fourth embodiment] An appearance of an inverter device according to a fourth embodiment is the same as that of the inverter device according to the first embodiment shown in FIG. 1. In addition, a state in which the inverter device according to the fourth embodiment is mounted in a vehicle is the same as in FIG. 2. Here, the fourth embodiment of the disclosure will be described with reference to FIG. 1 and FIG. 2. In the fourth embodiment, components the same as the first embodiment, the second embodiment, and the third embodiment will be denoted with the same reference numerals. In the fourth embodiment, the inverter device 1 has a housing 302 in place of the housing 2 of the first embodiment. In the fourth embodiment, unless otherwise noted, components in place of the components in the first embodiment, the second embodiment, and the third embodiment are the same components in the first embodiment, the second embodiment, and the third embodiment.

FIG. 12 is a cross-sectional view of the housing 302 corresponding to the V-V arrow in FIG. 1. The housing 302 houses the motor drive device 31 and the charger 36.

The housing 302 has a partition wall 307 in place of the partition wall 7 of the first embodiment. The housing 302 has a first housing part 307e in place of the first housing part 7e of the first embodiment. The housing 302 has a second housing part 307f in place of the second housing part 7f of the first embodiment. The housing 302 has a first side wall 308 in place of the first side wall 8 of the first embodiment. The housing 302 has a second side wall 309 in place of the second side wall 9 of the first embodiment. The housing 302 has an inlet 310 in place of the inlet 10 of the first embodiment. The housing 302 has an outlet 311 in place of the outlet 11 of the first embodiment. The housing 302 has a battery connecting part 312 in place of the battery connecting part 12 of the first embodiment. The housing 302 has an external power supply connecting part 313 in place of the external power supply connecting part 13 of the first embodiment. The housing 302 has a motor connecting part 314 in place of the motor connecting part 14 of the first embodiment. The housing 302 has a battery connecting part 315 in place of the battery connecting part 15 of the first embodiment.

The partition wall 307 has a first surface 307a in place of the first surface 7a of the first embodiment. The partition wall 307 has a second surface 307b in place of the second surface 7b of the first embodiment. The partition wall 307 has a second cooling flow path 320b in place of the second cooling flow path 20b of the first embodiment. The partition wall 307 has a fourth cooling flow path 320d in place of the fourth cooling flow path 20d of the first embodiment.

<Disposition of First Heating Element 30 and Second Heating Element 35>

The first heating element 30 is housed in the first housing part 307e. The first heating element 30 is disposed in contact with the first surface 307a of the partition wall 307. The first heating element 30 is disposed to face the second cooling flow path 320b. The second heating element 35 is housed in the second housing part 307f. The second heating element 35 is disposed in contact with the second surface 307b of the partition wall 307. The second heating element 35 is disposed to face the second cooling flow path 320b.

The first heating element 30 is fixed to the first surface 307a of the partition wall 307 with the first fixing part 30a and the second fixing part 30b. The second heating element 35 is fixed to the second surface 307b of the partition wall 307 with the first fixing part 35a and the second fixing part 35b. As shown in FIG. 12, the second cooling flow path 320b facing the first heating element 30 and the second heating element 35 in the Z axis direction is positioned between the first fixing part 30a of the first heating element 30 and the first fixing part 35a of the second heating element 35. In addition, as shown in FIG. 12, the second cooling flow path 320b facing the first heating element 30 and the second heating element 35 in the Z axis direction is positioned between the second fixing part 30b of the first heating element 30 and the second fixing part 35b of the second heating element 35. Therefore, the second cooling flow path 320b can be disposed at a position at which the first heating element 30 and the second heating element 35 can be cooled, and it is possible to efficiently cool the first heating element 30 and the second heating element 35 with the refrigerant that flows through the second cooling flow path 320b.

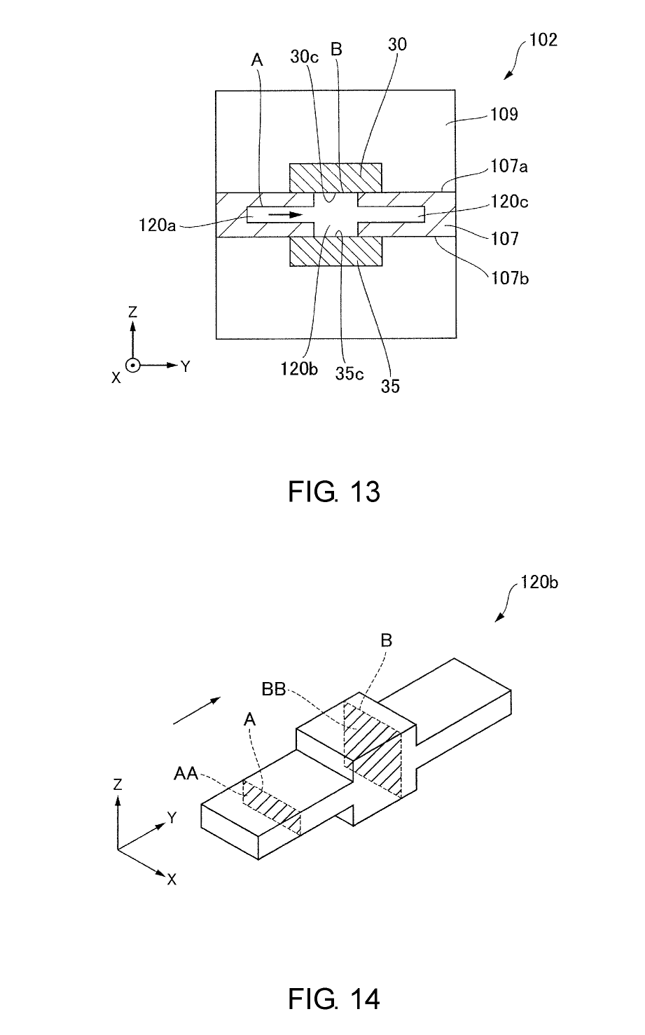

In FIG. 12, the thickness of the partition wall 307 between the second cooling flow path 320b and the first heating element 30 at a position at which the second cooling flow path 320b faces the first heating element 30 is the same as the thickness of the partition wall 307 at the position of the first fixing part 30a. The thickness of the partition wall 307 between the second cooling flow path 320b and the first heating element 30 at a position at which the second cooling flow path 320b faces the first heating element 30 may be thinner than the thickness of the partition wall 307 at the position of the first fixing part 30a.

[First modified example] Modified examples of the shape of the cooling flow path in the above embodiments will be described below. FIG. 13 is a diagram for explaining a first modified example of the disclosure and is a cross-sectional view of the housing 102 corresponding to the XIII-XIII arrow in FIG. 9. FIG. 14 is a perspective view of the second cooling flow path 120b in FIG. 13. In FIG. 13 and FIG. 14, arrows in the drawings indicate directions in which a refrigerant flows. The end in the −Y direction of the second cooling flow path 120b in FIG. 13 is connected to the first cooling flow path 120a. The end in the +Y direction of the second cooling flow path 120b in FIG. 13 is connected to the third cooling flow path 120c. The refrigerant flows from the first cooling flow path 120a to the second cooling flow path 120b. The refrigerant flows from the second cooling flow path 120b to the third cooling flow path 120c. As shown in FIG. 9, the second cooling flow path 120b opens to the side (+Z direction side) of the first surface 107a and opens to the side (−Z direction side) of the second surface 107b.

Here, as shown in FIG. 14, at a position A on the second cooling flow path 120b that does not open to the side of the first surface 107a and the side of the second surface 107b, a cross-sectional area of the second cooling flow path 120b in a direction orthogonal to the flow of the refrigerant is set as AA. In addition, as shown in FIG. 14, at a position B on the second cooling flow path 120b that opens to the side of the first surface 107a and the side of the second surface 107b, a cross-sectional area of the second cooling flow path 120b in a direction orthogonal to the flow of the refrigerant is set as BB. In this case, the area AA is smaller than the area BB. For this reason, it is thought that pressure drop occurs in the flow of the refrigerant in the second cooling flow path 120b.

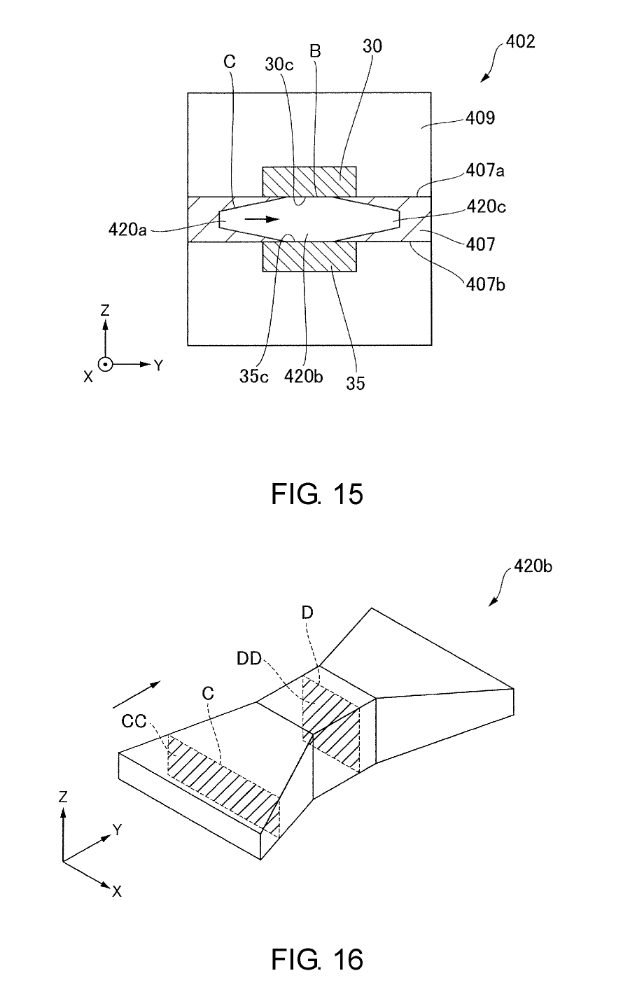

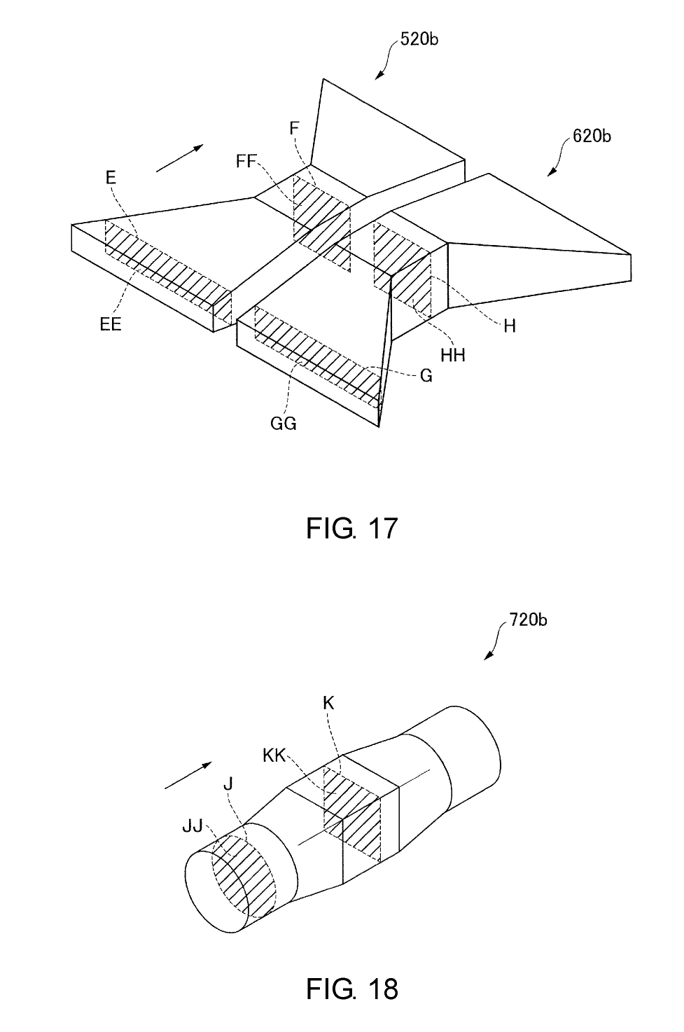

Therefore, in the first modified example, an example in which cross-sectional areas of the cooling flow path in a direction orthogonal to the flow of the refrigerant are the same at different positions in the flowing direction of the refrigerant will be described. According to the first modified example, it is possible to reduce pressure drop occurring in the flow of the refrigerant in the cooling flow path accordingly. FIG. 15 is a diagram corresponding to FIG. 13 and is a cross-sectional view of a housing 402 of the first modified example. FIG. 16 is a perspective view of a second cooling flow path 420b in FIG. 15. In FIG. 15 and FIG. 16, arrows in the drawings indicate directions in which a refrigerant flows.

The housing 402 has a partition wall 407 in place of the partition wall 7 of the first embodiment. The housing 402 has a second side wall 409 in place of the second side wall 9 of the first embodiment. The partition wall 407 has a first surface 407a in place of the first surface 7a of the first embodiment. The partition wall 407 has a second surface 407b in place of the second surface 7b of the first embodiment. The partition wall 407 has a first cooling flow path 420a in place of the first cooling flow path 20a of the first embodiment. The partition wall 407 has the second cooling flow path 420b in place of the second cooling flow path 20b of the first embodiment. The partition wall 407 has a third cooling flow path 420c in place of the third cooling flow path 20c of the first embodiment. The end in the −Y direction of the second cooling flow path 420b in FIG. 15 is connected to the first cooling flow path 420a. The end in the +Y direction of the second cooling flow path 420b in FIG. 15 is connected to the third cooling flow path 420c. The refrigerant flows from the first cooling flow path 420a to the second cooling flow path 420b. The refrigerant flows from the second cooling flow path 420b to the third cooling flow path 420c. The second cooling flow path 420b opens to the side (+Z direction side) of the first surface 407a and opens to the side (−Z direction side) of the second surface 407b. In the first modified example, as shown in FIG. 16, a cross-sectional area CC at a position C on the second cooling flow path 420b is the same as a cross-sectional area DD at a position D on the second cooling flow path 420b. Thus, it is possible to reduce pressure drop occurring in the flow of the refrigerant in the cooling flow path.

[Second modified example] In a second modified example, a case in which two cooling flow paths are adjacent to each other is shown. FIG. 17 is a perspective view of cooling flow paths 520b and 620b of the second modified example. In FIG. 17, the arrow in the drawing indicates a direction in which a refrigerant flows. In the example shown in FIG. 16, in order to make the cross-sectional area DD at the position D equal to the cross-sectional area CC at the position C, at the position C, the width (the length in the X axis direction) of the second cooling flow path 420b is widened in both directions including the +X direction and the −X direction, compared to the position A in FIG. 14. On the other hand, as shown in FIG. 17, when the cooling flow path 520b and the cooling flow path 620b are disposed close to each other in the width direction (X axis direction), if the widths (the lengths in the X axis direction) widen toward each other, there is a risk of the flow paths connecting. Thus, in this case, the widths (the lengths in the X axis direction) may widen away from each other.

[Third modified example] In a third modified example, a case in which the cross-sectional shape of the cooling flow path differs depending on the location is shown. FIG. 18 is a perspective view of a cooling flow path 720b of the third modified example. In FIG. 18, the arrow in the drawing indicates a direction in which a refrigerant flows. In the example in FIG. 18, the cross-sectional shape at a position J is a circle, and the cross-sectional shape at a position K is a rectangle. In this case also, when a cross-sectional area JJ at the position J is made equal to a cross-sectional area KK at the position K, it is possible to reduce pressure drop occurring in the flow of the refrigerant in the cooling flow path.

<Operations and Effects of Inverter Device 1>

Next, operations and effects of the inverter device 1 will be described.

(1) In the disclosure according to the above embodiment, the cooling flow path 20 is positioned between the first fixing part 30a and the second fixing part 30b. Therefore, the cooling flow path 20 can be disposed at a position at which the first heating element 30 can be cooled, and it is possible to efficiently cool the heating element with the refrigerant flowing through the cooling flow path 20. In addition, it is possible to provide an inverter device in which components are disposed in order to satisfy the demand. In addition, it is possible to provide an inverter device having features regarding the disposition of components.

(2) In addition, the plurality of fixing parts (the first fixing part 30a, the second fixing part 30b, the first fixing part 35a, and the second fixing part 35b) are bolts. Therefore, it is possible to fix the heating element (the first heating element 30, and the second heating element 35) to the partition wall 7 simply and firmly with the bolts.

(3) In addition, the thickness at a position at which the cooling flow path 20 faces the heating element (the first heating element 30 and the second heating element 35) is smaller than the length of the bolt. Therefore, it is possible to cool the heating element more efficiently by bringing the refrigerant flowing through the cooling flow path 20 closer thereto.

(4) In addition, the cooling flow path 20 is positioned between the first fixing part (the first fixing part 30a) and the second fixing part (the second fixing part 30b), and the cooling flow path 20 is positioned between the third fixing part (the first fixing part 35a) and the fourth fixing part (the second fixing part 35b). Therefore, the cooling flow path 20 can be disposed at a position at which the first heating element 30 and the second heating element 35 can be cooled, and it is possible to efficiently cool the first heating element 30 and the second heating element 35 with the refrigerant flowing through the cooling flow path 20.

(5) In addition, the cross-sectional shape of the cooling flow path 20 is a rectangular shape. Therefore, one side of the rectangle can made face the heating element (the first heating element 30 and the second heating element 35), and it is possible to efficiently cool the heating element with the refrigerant flowing through the cooling flow path 20.

(6) In addition, the thickness at a position at which the second cooling flow path 20b faces the first heating element 30 is smaller than the thickness at a position of the first fixing part 30a. Therefore, it is possible to cool the first heating element 30 more efficiently by bringing the refrigerant flowing through the second cooling flow path 20b closer thereto.

(7) In addition, the cross-sectional area of the cooling flow path 20 is constant. Therefore, it is possible to reduce pressure drop received when the refrigerant flows through the cooling flow path 20, and it is possible to efficiently cool the heating element (the first heating element 30 and the second heating element 35).

(8) In addition, the first inverter unit is the inverter unit for motor driving 32, and the second inverter unit is the inverter unit for a charger 37. Therefore, it is possible to efficiently cool the first heating element 30 of the inverter unit for motor driving 32 and the second heating element 35 of the inverter unit for a charger 37 along the cooling flow path 20, and it is possible to reduce the size of the device by effectively utilizing a space in which the first heating element 30 of the inverter unit for motor driving 32, the second heating element 35 of the inverter unit for a charger 37, and the cooling flow path 20 are disposed.

(9) In addition, the first heating element 30 is a heating element for motor driving and the second heating element 35 is a heating element for a charger. Therefore, it is possible to efficiently cool the heating element for motor driving and the heating element for a charger along the cooling flow path 20, and it is possible to reduce the size of the device by effectively utilizing a space in which the heating element for motor driving, the heating element for a charger, and the cooling flow path 20 are disposed.

(10) In addition, the first heating element 30 has a plurality of switching elements, and the second heating element 35 has a plurality of switching elements. Therefore, it is possible to efficiently cool the switching elements along the cooling flow path 20, and it is possible to reduce the size of the device by effectively utilizing a space in which the switching elements and the cooling flow path 20 are disposed.

(11) In addition, the plurality of switching elements of the first heating element 30 and the second heating element 35 are IGBTs. Therefore, it is possible to efficiently cool IGBTs along the cooling flow path 20, and it is possible to reduce the size of the device by effectively utilizing a space in which IGBTs and the cooling flow path are disposed.

(12) In addition, the first side wall 8, the second side wall 9, and the partition wall 7 form an H shape. Therefore, a part to which the first heating element 30 is fixed and a part to which the second heating element 35 is fixed can be protected with the first side wall 8 and the second side wall 9. In addition, in a direction parallel to the first surface 7a and the second surface 7b of the partition wall 7, since one end and the other end (X axis direction end) of the partition wall 7 do not protrude from the first side wall 8 and the second side wall 9, it is possible to reduce the size of the housing.

(13) In addition, the first housing part 7e in which the inverter unit for motor driving 32 is housed and the second housing part 7f in which the inverter unit for a charger 37 is housed are provided. Therefore, the inverter unit for motor driving 32 and the inverter unit for a charger 37 can be housed in one housing 2 and it is possible to perform housing efficiently.

(14) In addition, the second housing part 7f has the battery connecting part 15. Therefore, a voltage controlled by the inverter unit for a charger 37 housed in the second housing part 7f can be supplied to the battery 805.

(15) In addition, the second housing part 7f has the external power supply connecting part 13. Therefore, a voltage from the external power supply 900 can be supplied to the inverter unit for a charger 37 housed in the second housing part 7f.

(16) In addition, the inlet 10 is disposed on the first side wall 8, and the outlet 11 is disposed on the second side wall 9. Therefore, it is possible to secure the length of the cooling flow path 20 from the first side wall 8 to the second side wall 9 via the partition wall 7, and it is possible to efficiently cool the first heating element 30 and the second heating element 35.

(17) In addition, the inlet 10 is disposed on the first side wall 8, and the outlet 11 is disposed on the first side wall 8. Therefore, it is possible to secure the length of the cooling flow path 20 from the first side wall 8 returning to the first side wall 8 via the partition wall 7, and it is possible to efficiently cool the first heating element 30 and the second heating element 35.

(18) In addition, the housing 2 of the inverter device 1 has the motor connecting part 14 connected to the traction motor 806. Therefore, the inverter unit housed in the housing 2 of the inverter device 1 can be used as the inverter unit for motor driving 32.

(19) In addition, in the vehicle 800, the cooling flow path 20 is positioned between the first fixing part 30a and the second fixing part 30b, and the cooling flow path 20 is positioned between the third fixing part 35a and the fourth fixing part 35b. Therefore, the cooling flow path 20 can be disposed at a position at which the heating element for motor driving (the first heating element 30) and the heating element for a charger (the second heating element 35) can be cooled, and it is possible to efficiently cool the heating element for motor driving and the heating element for a charger with the refrigerant flowing through the cooling flow path 20.

Applications of the inverter devices of the above embodiments are not particularly limited. The inverter devices of the above embodiments are mounted in, for example, a vehicle. In addition, the above components can be appropriately combined within a range in which they are not mutually exclusive.

While some embodiments of the disclosure have been described above, the disclosure is not limited to these embodiments, and various modifications and alternations can be made within the scope of the gist thereof. These embodiments and modifications thereof are included in the scope and gist of the disclosure and also included in the disclosure described in the scope of the claims and the scope equivalent thereto.

What is claimed is:

1. An inverter device, comprising:
an inverter unit; and
a housing in which the inverter unit is housed,
wherein the inverter unit includes a heating element,
wherein the housing has
a partition wall having a cooling flow path through which a refrigerant flows, and
a plurality of fixing parts for fixing the heating element to the partition wall,
wherein the plurality of fixing parts include
a first fixing part disposed at one side of the heating element, and
a second fixing part disposed at the other side of the heating element, and
wherein the cooling flow path is positioned between the first fixing part and the second fixing part.

2. The inverter device according to claim 1,
wherein the plurality of fixing parts are bolts.

3. The inverter device according to claim 2,
wherein the thickness of the partition wall between the cooling flow path and the heating element at a position at which the cooling flow path faces the heating element is smaller than the length of the bolt.

4. The inverter device according to claim 1,
wherein the inverter unit includes
a first inverter unit, and
a second inverter unit,
wherein the first inverter unit includes a first heating element,
wherein the second inverter unit includes a second heating element,
wherein the first fixing part is disposed at one side of the first heating element,
wherein the second fixing part is disposed at the other side of the first heating element,
wherein the plurality of fixing parts further include
a third fixing part disposed at one side of the second heating element, and
a fourth fixing part disposed at the other side of the second heating element, and
wherein the cooling flow path is positioned between the third fixing part and the fourth fixing part.

5. The inverter device according to claim 4,
wherein the cross-sectional shape of the cooling flow path in a direction orthogonal to a direction in which the refrigerant flows is a rectangular shape.

6. The inverter device according to claim 4,
wherein the thickness of the partition wall between the cooling flow path and the heating element at a position at which the cooling flow path faces the heating element is thinner than the thickness of the partition wall at a position of the plurality of fixing parts.

7. The inverter device according to claim 4,
wherein, in a direction in which the refrigerant flows through the cooling flow path, the cross-sectional area of the cooling flow path in a direction orthogonal to the direction in which the refrigerant flows is constant.

8. The inverter device according to claim 4,
wherein the inverter device is a device used for a vehicle in which a motor and a battery are mounted,
wherein the first inverter unit is an inverter unit for motor driving that supplies power from the battery to the motor, and
wherein the second inverter unit is an inverter unit for a charger that charges the battery.

9. The inverter device according to claim 8,
wherein the first heating element is a heating element for motor driving, and
wherein the second heating element is a heating element for a charger.

10. The inverter device according to claim 9,
wherein the first heating element has a plurality of switching elements, and
wherein the second heating element has a plurality of switching elements.

11. The inverter device according to claim 10,
wherein the plurality of switching elements of the first heating element and the second heating element are a plurality of IGBTs.

12. The inverter device according to claim 8,
wherein the first heating element is fixed to a first surface of the partition wall,
wherein the second heating element is fixed to a second surface which is a reverse surface with respect to the first surface of the partition wall,
wherein the housing has
a first side wall that extends to the side protruding from the first surface and to the side protruding from the second surface at one end of the partition wall, and
a second side wall that extends to the side protruding from the first surface and to the side protruding from the second surface at the other end of the partition wall, and
wherein the first side wall, the second side wall, and the partition wall form an H shape.

13. The inverter device according to claim 12,
wherein the housing has
a first housing part in which the inverter unit for motor driving is housed, and
a second housing part in which the inverter unit for a charger is housed,
wherein the partition wall partitions the first housing part from the second housing part,
wherein the first housing part is partitioned off by the side of the first surface of the partition wall, the second side wall, and the first side wall, and
wherein the second housing part is partitioned off by the side of the second surface of the partition wall, the second side wall, and the first side wall.

14. The inverter device according to claim 13,
wherein the second housing part has a battery connecting part connected to the battery.

15. The inverter device according to claim 13,
wherein the second housing part has an external power supply connecting part connected to an external power supply.

16. The inverter device according to claim 12,
wherein an inlet into which the refrigerant flowing through the cooling flow path flows is disposed on the first side wall, and
wherein an outlet from which the refrigerant flowing through the cooling flow path is discharged is disposed on the second side wall.

17. The inverter device according to claim 12,
wherein an inlet into which the refrigerant flowing through the cooling flow path flows is disposed on the first side wall, and
wherein an outlet from which the refrigerant flowing through the cooling flow path is discharged is disposed on the first side wall.

18. The inverter device according to claim 8,
wherein the housing has a motor connecting part connected to the motor.

19. A vehicle, comprising:
a motor;
a battery;
an inverter unit for motor driving configured to supply power from the battery to the motor;
an inverter unit for a charger configured to charge the battery; and
a housing in which the inverter unit for motor driving and the inverter unit for a charger are housed,
wherein, in a vehicle that runs according to rotation of the motor,
the inverter unit for motor driving has a heating element for motor driving, and
the inverter unit for a charger includes a heating element for a charger,
wherein the housing has
a partition wall having a cooling flow path through which a refrigerant flows,
a first fixing part for fixing one side of the heating element for motor driving to the partition wall,
a second fixing part for fixing the other side of the heating element for motor driving to the partition wall,
a third fixing part for fixing one side of the heating element for a charger to the partition wall, and
a fourth fixing part for fixing the other side of the heating element for a charger to the partition wall,
wherein the cooling flow path is positioned between the first fixing part and the second fixing part, and
wherein the cooling flow path is positioned between the third fixing part and the fourth fixing part.
